(19) United States
(12) Patent Application Publication
(10) Pub. No.: US 2026/0118984 A1
(43) Pub. Date: Apr. 30, 2026

(54) TOUCH DISPLAY DEVICE

(71) Applicant: LG Display Co., Ltd., Seoul (KR)

(72) Inventors: Jinsuk LEE, Paju-si (KR); MinHo OH, Paju-si (KR)

(73) Assignee: LG Display Co., Ltd., Seoul (KR)

(21) Appl. No.: 19/187,788

(22) Filed: Apr. 23, 2025

(30) Foreign Application Priority Data
Oct. 31, 2024 (KR) 10-2024-0151776

(51) Int. Cl. G06F 3/041; G06F 3/044; G09G 3/3233; H10K 59/40; H10K 59/80

(52) U.S. Cl. CPC G06F 3/0412; G06F 3/04164; H10K 59/40; H10K 59/873; G06F 3/044; G09G 3/3233; G09G 2300/0842; G09G 2354/00

(57) ABSTRACT

A touch display device according to embodiments of the disclosure may comprise a substrate including a display area and a non-display area adjacent to the display area, a pixel electrode disposed on the substrate, a common electrode disposed on the pixel electrode, a first inorganic encapsulation layer disposed on the common electrode, an organic encapsulation layer disposed on the first inorganic encapsulation layer, a second inorganic encapsulation layer disposed on the organic encapsulation layer, and a touch sensor disposed on the second inorganic encapsulation layer. A dielectric constant of the first inorganic encapsulation layer may be smaller than a dielectric constant of the second inorganic encapsulation layer, and a dielectric constant of the organic encapsulation layer may be smaller than the dielectric constant of the first inorganic encapsulation layer. This layered encapsulation structure may reduce parasitic capacitance and enhance touch sensitivity while maintaining improved resistance to moisture and oxygen permeation.

### CROSS-REFERENCE TO RELATED APPLICATION

This application claims priority from Korean Patent Application No. 10-2024-0151776, filed on Oct. 31, 2024, which is hereby incorporated by reference for all purposes as if fully set forth herein.

### BACKGROUND

### Technical Field

Embodiments of the disclosure relate to a touch display device.

### Description of the Related Art

Among others, touch display devices provide an input scheme that allows users easier and more intuitive and convenient entry of information or commands without the need for buttons, a keyboard, a mouse, or other typical input means.

The touch display device may include a plurality of touch electrodes for touch sensing, and a plurality of touch routing lines for connecting the plurality of touch electrodes to pad portions. A plurality of touch metals for forming the plurality of touch electrodes and the plurality of touch routing lines may be disposed on an encapsulation layer for protecting an organic-based light emitting element in the display panel from physical impact, oxygen, and/or moisture.

### BRIEF SUMMARY

The disclosed touch display device features a multi-layer encapsulation structure designed to enhance touch sensitivity while maintaining strong moisture resistance. The encapsulation stack includes a first inorganic layer, an organic layer, and a second inorganic layer, arranged such that their dielectric constants increase from the outermost touch sensor interface to the underlying OLED structure. This specific dielectric layering reduces parasitic capacitance between the touch sensor and the common electrode, improving touch performance without compromising the protective barrier for sensitive organic materials.

Additionally, the first inorganic layer may include multiple sub-layers with progressively decreasing dielectric constants closer to the touch sensor, further suppressing unwanted capacitance. The touch sensor itself is embedded directly on the encapsulation layer and aligned to avoid overlap with emission areas, increasing luminous efficiency. Touch routing lines are also shaped to follow the encapsulation profile, supporting compact and efficient integration within the display panel.

For example, embodiments of the disclosure may provide a touch display device having an encapsulation layer with excellent anti-moisture permeation properties.

Embodiments of the disclosure may provide a touch display device having an encapsulation layer capable of reducing parasitic capacitance.

Embodiments of the disclosure may provide a touch display device capable of enhancing touch sensitivity.

A touch display device according to embodiments of the disclosure may comprise a substrate including a display area and a non-display area surrounding the display area, a pixel electrode disposed on the substrate, a common electrode disposed on the pixel electrode, a first inorganic encapsulation layer disposed on the common electrode, an organic encapsulation layer disposed on the first inorganic encapsulation layer, a second inorganic encapsulation layer disposed on the organic encapsulation layer, and a touch sensor disposed on the second inorganic encapsulation layer. A dielectric constant of the first inorganic encapsulation layer may be smaller than a dielectric constant of the second inorganic encapsulation layer, and a dielectric constant of the organic encapsulation layer may be smaller than the dielectric constant of the first inorganic encapsulation layer.

A touch display device according to embodiments of the disclosure may comprise a substrate including a display area and a non-display area surrounding the display area, a pixel electrode disposed on the substrate, a common electrode disposed on the pixel electrode, an encapsulation layer disposed on the common electrode, and a plurality of touch sensors disposed on the encapsulation layer. The encapsulation layer may further include a first inorganic encapsulation layer including a plurality of inorganic layers, an organic encapsulation layer disposed on the first inorganic encapsulation layer, and a second inorganic encapsulation layer disposed on the organic encapsulation layer. Among the plurality of inorganic layers, an inorganic layer closer to the touch sensor may have a smaller dielectric constant.

According to an embodiment of the disclosure, there may be provided a touch display device having an encapsulation layer with excellent anti-moisture permeation properties.

According to embodiments of the disclosure, there may be provided a touch display device having an encapsulation layer capable of reducing parasitic capacitance.

According to embodiments of the disclosure, there may be provided a touch display device capable of enhancing touch sensitivity.

According to embodiments of the disclosure, there may be provided a display device capable of reducing power consumption by reducing additional driving for compensating for signal transfer by enhancing touch sensitivity.

### DESCRIPTION OF THE SEVERAL VIEWS OF THE DRAWINGS

The above and other objects, features, and advantages of the disclosure will be more clearly understood from the following detailed description, taken in conjunction with the accompanying drawings, in which:

FIG. 1 illustrates a touch display device according to embodiments of the disclosure;

FIG. 2 illustrates a display panel according to an embodiment of the disclosure;

FIG. 3 is a cross-sectional view illustrating a display panel according to embodiments of the disclosure;

FIG. 4 is a cross-sectional view illustrating a portion of a display area in a display panel according to embodiments of the disclosure;

FIG. 5 is a cross-sectional view illustrating a detailed configuration of an encapsulation layer in a display panel according to embodiments of the disclosure;

FIG. 6 is a cross-sectional view illustrating a portion of a display area in a display panel according to embodiments of the disclosure;

FIG. 7 illustrates display touch noise simulation results according to an embodiment of the disclosure and a comparative example; and

FIG. 8 is a cross-sectional view illustrating a portion of a non-display area in a display panel according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

To further elaborate, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, various embodiments of the disclosure are described in detail with reference to the accompanying drawings.

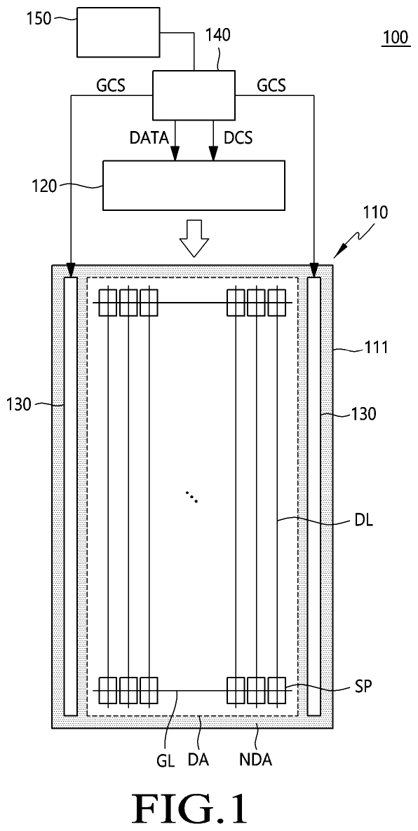

FIG. 1 is a view illustrating a system configuration of a touch display device 100 according to embodiments of the disclosure.

Referring to FIG. 1, a transparent touch display device 100 according to embodiments of the disclosure may include a display panel 110 and display driving circuits, as components for displaying images. The display driving circuit may be a circuit for driving the display panel 110. The display driving circuits may include a data driving circuit 120, a gate driving circuit 130, and a controller 140, but embodiments of the disclosure are not limited thereto.

The display panel 110 may include a substrate 111 and a plurality of subpixels SP disposed on the substrate 111.

The substrate 111 may include a display area DA and a non-display area NDA.

The display area DA is an area where images may be displayed, and may also be referred to as an active area. A plurality of subpixels SP for image display may be disposed in the display area DA. The non-display area NDA is an area where no image is displayed and may be an area outside the display area DA. The non-display area NDA may also be referred to as a bezel (or bezel area). The non-display area NDA may include a pad area (also referred to as a pad portion).

For example, the non-display area NDA may include a first non-display area around the display area DA, a second non-display area including a pad area, and a bending area between the first non-display area and the second non-display area.

In the pad area, a driving circuit may be connected or bonded (or attached). As the bending area is bent, the bending area and the second non-display area may be disposed behind the first non-display area to be invisible from the front. The first non-display area may have a very small size. Embodiments of the disclosure are not limited thereto.

No or little change may be made to the non-display area NDA shown to the user when the user views the touch display device 100 from the front, but embodiments of the disclosure are not limited thereto.

The touch display device 100 according to embodiments of the disclosure may be a self-luminous touch display device in which the display panel 110 emits light by itself, but embodiments of the disclosure are not limited thereto. When the touch display device 100 according to the embodiments of the disclosure is a self-luminous touch display device, each of the plurality of subpixels SP may include a light emitting element.

For example, the touch display device 100 according to embodiments of the disclosure may be an organic light emitting touch display device in which the light emitting element is implemented as an organic light emitting diode (OLED). As another example, the touch display device 100 according to embodiments of the disclosure may be an inorganic light emitting touch display device in which the light emitting element is implemented as an inorganic material-based light emitting diode. As another example, the display device 100 according to embodiments of the disclosure may be a quantum dot touch display device in which the light emitting element is implemented as a quantum dot which is self-luminous semiconductor crystal. As another example, the touch display device 100 according to embodiments of the disclosure may be a micro LED touch display device or a mini LED touch display device.

The structure of each of the plurality of subpixels SP may vary according to the type of the touch display device 100. For example, when the touch display device 100 is a self-luminous touch display device in which the subpixels SP emit light by themselves, each subpixel SP may include a light emitting element that emits light by itself, one or more transistors, and one or more capacitors, but embodiments of the disclosure are not limited thereto.

Various types of signal lines for driving a plurality of subpixels SP may be disposed on the substrate 111 of the display panel 110. For example, various types of signal lines may include a plurality of data lines DL transferring data signals (also referred to as data voltages or image signals) to a plurality of subpixels SP and a plurality of gate lines GL transferring gate signals (also referred to as scan signals) to the plurality of subpixels SP.

The plurality of data lines DL and the plurality of gate lines GL may cross each other. Each of the plurality of gate lines GL may be disposed to extend in a first direction (e.g., a row direction or column direction). Each of the plurality of data lines DL may be disposed to extend in a second direction (e.g., a column direction or row direction) different from the first direction.

According to embodiments of the disclosure, e.g., the first direction may be the row direction, and the second direction may be the column direction. As another example, the first direction may be the column direction, and the second direction may be the row direction. The row direction and the column direction may be relative directions. For example, the column direction may be the row direction depending on the viewpoint, and the row direction may be the column direction depending on the viewpoint. For convenience of description, described below is an example in which each of the plurality of data lines DL is disposed in the column direction, and each of the plurality of gate lines GL is disposed in the row direction, but embodiments of the disclosure are not limited thereto. In embodiments of the disclosure, the angle between the first direction and the second direction may be 90 degrees or may an angle different from 90 degrees.

The data driving circuit 120 may be a circuit for driving the plurality of data lines DL, and may out data signals to the plurality of data lines DL.

The data driving circuit 120 may receive digital image data DATA from the controller 140 and may convert the received image data DATA into analog data signals (or also referred to as data voltages) and output them to the plurality of data lines DL.

For example, the data driving circuit 120 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110, but embodiments of the disclosure are not limited thereto.

The data driving circuit 120 may be connected to one side (e.g., an upper or lower side) of the display panel 110. As another example, depending on the driving scheme or the panel design scheme, data driving circuits 120 may be connected with both the sides (e.g., both the upper and lower sides) of the display panel 110, or two or more of the four sides of the display panel 110.

The data driving circuit 120 may be connected outside the display area DA of the display panel 110, but as another example, the data driving circuit 120 may be disposed in the display area DA of the display panel 110.

The gate driving circuit 130 is a circuit for driving the plurality of gate lines GL, and may output gate signals to the plurality of gate lines GL.

The gate driving circuit 130 may receive a first gate voltage corresponding to a turn-on voltage (or also referred to as a turn-on level voltage) and a second gate voltage corresponding to a turn-off voltage (or also referred to as a turn-off level voltage) together with various gate driving control signals GCS, generate gate signals including a section having the first gate voltage and a section having the second gate voltage for a predetermined time (e.g., one frame time), and supply the generated gate signals to the plurality of gate lines GL. For example, the turn-on level voltage may be a high level voltage, and the turn-off level voltage may be a low level voltage. As another example, the turn-on level voltage may be a low level voltage, and the turn-off level voltage may be a high level voltage.

In the touch display device 100 according to embodiments of the disclosure, the gate driving circuit 130 may be embedded, in a gate in panel (GIP) type, in the display panel 110, but embodiments of the disclosure are not limited thereto. When the gate driving circuit 130 is of the gate in panel type, the gate driving circuit 130 may be formed on the substrate 111 of the display panel 110 during the manufacturing process of the display panel 110. When the gate driving circuit 130 is of a gate-in-panel type, the gate driving circuit 130 may be referred to as a gate-in-panel circuit (GIPC).

For example, the gate driving circuit 130 may be disposed in the non-active area NDA of the display panel 110. As another example, the gate driving circuit 130 may be disposed in the display area DA of the display panel 110. For example, the gate driving circuit 130 may be disposed in a first partial area in the display area DA (e.g., a left area or a right area in the display area DA). As another example, the gate driving circuit 130 may be disposed in a first partial area in the display area DA (e.g., a left area or right area in the display area DA) and a second partial area (e.g., a right area or left area in the display area DA). As another example, the gate driving circuit 130 may be disposed over the entire display area DA.

When the gate driving circuit 130 is disposed in the display area DA of the display panel 110, the gate driving circuit 130 may vertically overlap the subpixels SP disposed in the display area DA. For example, the gate driving circuit 130 may vertically overlap the light emitting elements and transistors included in the disposed subpixels SP in the display area DA. The gate driving circuit 130 may vertically overlap a plurality of light emitting elements and a plurality of transistors included in a plurality of subpixels SP disposed in the display area DA. The gate driving circuit 130 may include a plurality of transistors. Each of the plurality of transistors included in the gate driving circuit 130 may include an active layer including a first semiconductor material, and each of the plurality of transistors included in the subpixels SP may include an active layer including a second semiconductor material. For example, the first semiconductor material and the second semiconductor material may be substantially identical. As another example, the first semiconductor material and the second semiconductor material may be different from each other. For example, the first semiconductor material may be a silicon-based semiconductor material (e.g., low temperature poly silicon), and the second semiconductor material may be an oxide semiconductor material. For example, the active layer may be, but is not limited to, a semiconductor layer.

The controller 140 is a device for controlling the data driving circuit 120 and the gate driving circuit 130 and may control driving timings for the plurality of data lines DL and driving timings for the plurality of gate lines GL.

The controller 140 may supply a data driving control signal DCS to the data driving circuit 120 to control the data driving circuit 120 and may supply a gate driving control signal GCS to the gate driving circuit 130 to control the gate driving circuit 130.

The controller 140 may receive input image data from the host system 150 and supply image data DATA to the data driving circuit 120 based on the input image data.

The controller 140 may be implemented as a separate component from the data driving circuit 120, or the controller 140 and the data driving circuit 120 may be integrated into an integrated circuit (IC).

The controller 140 may be a timing controller used in display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (A SIC), or a processor, but is not limited thereto.

The controller 140 may be mounted on a printed circuit board or a flexible printed circuit and may be electrically connected with the data driving circuit 120 and the gate driving circuit 130 through the printed circuit board or the flexible printed circuit.

The controller 140 may transmit/receive signals to/from the data driving circuit 120 according to one or more predetermined interfaces. The interface may include, e.g., a low voltage differential signaling (LVDS) interface, an embedded clock point-point interface (EPI), and a serial peripheral interface (SPI), but embodiments of the disclosure are not limited thereto.

The touch display device 100 according to embodiments of the disclosure may provide not only an image display function, but also a touch sensing function of detecting whether a touch is made by a touch object, such as a finger or a pen, or detecting the position of a touch.

The touch display device 100 according to embodiments of the disclosure may be a mobile terminal, such as a smart phone or a tablet, or a monitor or television (TV) in various sizes but, without limited thereto, may be a display in various types and various sizes capable of displaying information or images.

The touch display device 100 according to embodiments of the disclosure may further include an electronic device such as a camera (image sensor), a detection sensor, or the like. For example, the detection sensor may be a sensor that detects an object or a human body by receiving light such as infrared rays, ultrasonic waves, or ultraviolet rays, but embodiments of the disclosure are not limited thereto.

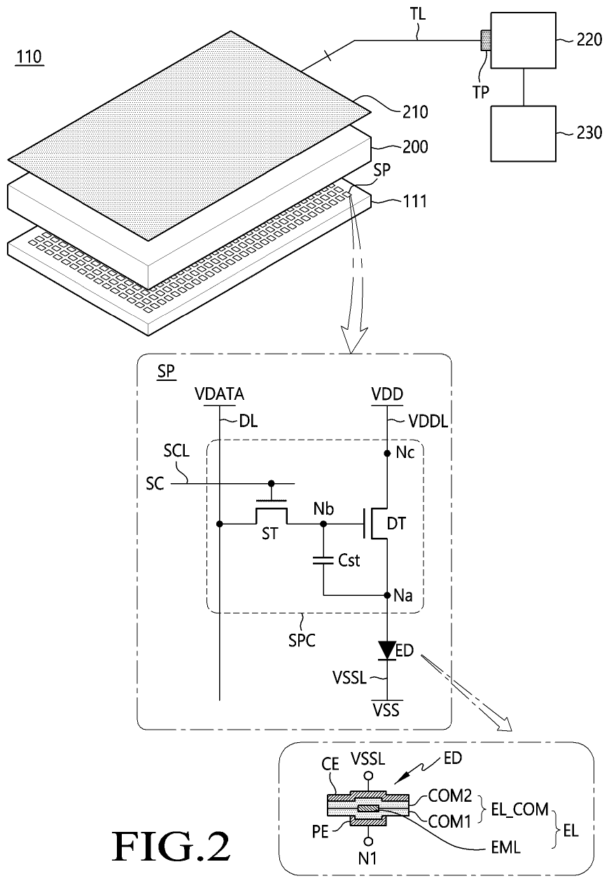

FIG. 2 illustrates a touch display device 100 according to embodiments of the disclosure.

Referring to FIG. 2, the display panel 110 according to embodiments of the disclosure may include a substrate 111 disposed in a plurality of subpixels SP and an encapsulation layer 200 on the substrate 111. The encapsulation layer 200 may also be referred to as an encapsulation substrate or an encapsulation unit.

Referring to FIG. 2, when the touch display device 100 according to embodiments of the disclosure is a self-luminous touch display device, each of the plurality of subpixels SP disposed on the substrate 111 may include a light emitting element ED and a subpixel circuit SPC for driving the light emitting element ED.

Referring to FIG. 2, the subpixel circuit SPC may include a plurality of transistors and at least one capacitor for driving the light emitting element ED, but embodiments of the disclosure are not limited thereto. In the disclosure, the subpixel circuit SPC may drive the light emitting element ED by supplying a driving current to the light emitting element ED at a predetermined timing. The light emitting element ED may be driven by a driving current to emit light.

The plurality of transistors may include a driving transistor DT for driving the light emitting element ED and a scan transistor ST that is turned on or off according to the scan signal SC.

The driving transistor DT may supply a driving current to the light emitting element ED. The scan transistor ST may be configured to control the electrical state of a corresponding node in the subpixel circuit SPC or to control the state or operation of the driving transistor DT. The at least one capacitor may include a storage capacitor Cst for maintaining a constant voltage during a frame.

To drive the subpixel SP, a data signal VDATA as an image signal and a scan signal SC which is a kind of gate signal may be applied to the subpixel SP. Further, for driving the subpixel SP, a common driving signal including the driving voltage VDD and the base voltage VSS may be applied to the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in all the subpixels SP. For example, the pixel electrode PE may be an anode, and the common electrode CE may be a cathode. As another example, the pixel electrode PE may be a cathode, and the common electrode CE may be an anode. For convenience of description, an example is described in which the pixel electrode PE is an anode, and the common electrode CE is a cathode.

When the light emitting element ED is an organic light emitting element, the intermediate layer EL may include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 may be collectively referred to as a common intermediate layer EL_COM.

The light emitting layer EML may be disposed for each subpixel SP or may be disposed commonly over a plurality of subpixels SP. The common intermediate layer EL_COM may be commonly disposed across the plurality of subpixels SP, but embodiments of the disclosure are not limited thereto.

In other words, the light emitting layer EML may be disposed for each emission area or disposed commonly across a plurality of emission areas. The common intermediate layer EL_COM may be commonly disposed across a plurality of emission areas and non-emission areas, but embodiments of the disclosure are not limited thereto.

For example, the first common intermediate layer COM1 may include a hole injection layer HIL, an electron blocking layer EBL, and a hole transport layer HTL, but embodiments of the disclosure are not limited thereto. The second common intermediate layer COM2 may include an electron transport layer ETL, a hole blocking layer HBL, and an electron injection layer EIL, but embodiments of the disclosure are not limited thereto.

The hole injection layer HIL may inject holes from the pixel electrode PE to the hole transport layer HTL, and the hole transport layer HTL may transport holes to the light emitting layer EML. The electron injection layer EIL may inject electrons from the common electrode CE to the electron transport layer ETL, and the electron transport layer ETL may transport electrons to the light emitting layer EML.

For example, the common electrode CE may be electrically connected to the base voltage line VSSL. The base voltage VSS, which is one type of the common voltage, may be applied to the common electrode CE through the base voltage line VSSL. The pixel electrode PE may be electrically connected directly or indirectly (through another transistor) to the first node Na of the driving transistor DT of each subpixel SP. In the disclosure, “base voltage VSS” may also be referred to as a first common voltage, a low-potential power voltage, or a low-potential voltage, and “base voltage line VSSL” may also be referred to as a first common voltage line, a low-potential power voltage line, or a low-potential voltage line.

Each light emitting element ED may include portions where the pixel electrode PE, the light emitting layer EML in the intermediate layer LE, and the common electrode CE overlap. A predetermined light emitting area may be formed by each light emitting element ED. For example, the light emitting area of each light emitting element ED may include an overlapping area of the pixel electrode PE, the light emitting layer EML in the intermediate layer EL, and the common electrode CE.

For example, the light emitting element ED may be an organic light emitting diode (OLED), an inorganic light emitting diode (LED), a quantum dot light emitting element, a micro LED, or a mini LED, but embodiments of the disclosure are not limited thereto. For example, when the light emitting element ED is an organic light emitting diode (OLED), the intermediate layer EL of the light emitting element ED may include an intermediate layer EL including an organic material.

The driving transistor DT may be a driving transistor for supplying a driving current to the light emitting element ED. The driving transistor DT may be connected between a driving voltage line VDDL and the light emitting element ED.

The driving transistor DT may include a first node Na, a second node Nb, and a third node Nc. The first node Na may be electrically connected to the light emitting element ED, the second node Nb may receive a data signal V DATA, and the third node Nc may receive a driving voltage VDD, which is another kind of common voltage, from the driving voltage line VDDL. The driving transistor DT may be connected on the first node Na and the third node Nc. In the disclosure, “driving voltage VDD” may also be referred to as a second common voltage, a high-potential power voltage, or a high-potential voltage, and “driving voltage line VDDL” may also be referred to as a second common voltage line, a low-potential power voltage line, or a low-potential voltage line.

In the driving transistor DT, the second node Nb may be a gate node, the first node Na may be a source node or a drain node, and the third node Nc may be a drain node or a source node. Hereinafter, for convenience of description, an example is described in which in the driving transistor DT, the second node Nb may be a gate node, the first node Na may be a source node, and the third node Nc may be a drain node, but embodiments of the disclosure are not limited thereto.

The scan transistor ST included in the subpixel circuit SPC illustrated in FIG. 2 may be a switching transistor for transferring the data signal VDATA, which is an image signal, to the second node Nb, which is the gate node of the driving transistor DT.

The scan transistor ST may be controlled to be turned on and off by the scan signal SC, which is a kind of gate signal applied through the scan line SCL, which is a type of the gate line GL, to control electrical connection between the second node Nb of the driving transistor DT and the data line DL. The drain electrode or the source electrode of the scan transistor ST may be electrically connected to the data line DL, the source electrode or the drain electrode of the scan transistor ST may be electrically connected to the second node Nb of the driving transistor DT, and the gate electrode of the scan transistor ST may be electrically connected to the scan line SCL.

The storage capacitor Cst may be electrically connected between the first node Na and second node Nb of the driving transistor DT. The storage capacitor Cst may include at least one capacitor electrode electrically connected to the first node Na of the driving transistor DT or corresponding to the first node Na of the driving transistor DT, and at least one capacitor electrode electrically connected to the second node Nb of the driving transistor DT or corresponding to the second node Nb of the driving transistor DT.

The capacitor Cst may be an external capacitor intentionally designed to be outside the driving transistor DT, but not a parasite capacitor (e.g., Cgs or Cgd) which is an internal capacitor that may be present between the first node Na and the second node Nb of the driving transistor DT, but embodiments of the disclosure are not limited thereto.

Each of the driving transistor DT and the scan transistor ST may be an n-type transistor or a p-type transistor, but embodiments of the disclosure are not limited thereto. For example, one of the driving transistor DT and the scan transistor ST may be either an n-type transistor or a p-type transistor.

The display panel 110 may have a top emission structure or a bottom emission structure. When the display panel 110 has a top emission structure, at least a portion of the subpixel circuit SPC may overlap at least a portion of the light emitting element ED in a vertical direction. Accordingly, the area of the emission area may increase and the aperture ratio may increase. When the display panel 110 has a bottom emission structure, the subpixel circuit SPC may not overlap the light emitting element ED in the vertical direction.

As illustrated in FIG. 2, the subpixel circuit SPC may have a 2T (Transistor) 1C (Capacitor) structure including two transistors DT and ST and one capacitor Cst. In some cases, the subpixel circuit SPC may further include one or more transistors or may further include one or more capacitors.

For example, the subpixel circuit SPC may have a 3T1C structure including 3 transistors and 1 capacitor. For example, the subpixel circuit SPC may have an 8T1C structure including 8 transistors and 1 capacitor. As another example, the subpixel circuit SPC may have a 6T2C structure including 6 transistors and 2 capacitors. As another example, the subpixel circuit SPC may have a 7T1C structure including 7 transistors and 1 capacitor. Embodiments of the disclosure are not limited thereto.

Depending on the structure of the subpixel circuit SPC, the type and number of gate lines or the gate signals supplied to the subpixel SP may vary. Further, the type and the number of common driving signals supplied to the subpixel SP may vary depending on the structure of the subpixel circuit SPC.

Since the circuit elements (e.g., the light emitting element ED implemented as an organic light emitting diode (OLED) including an organic material) in each subpixel SP are vulnerable to external moisture or oxygen, the encapsulation layer 200 may be disposed on the display panel 110. The encapsulation layer 200 may prevent external moisture or oxygen from penetrating into circuit elements (e.g., the light emitting element ED). The encapsulation layer 200 may be configured in various forms so that the light emitting elements ED do not contact moisture or oxygen. For example, the encapsulation layer 200 may be constituted of two or more layers in which organic films and inorganic films are alternately stacked, but embodiments of the disclosure are not limited thereto.

Referring to FIG. 2, a touch display device 100 according to embodiments of the disclosure may include a touch sensor layer 210 in which a touch sensor is formed, and a touch sensing circuit that senses the touch sensor formed in the touch sensor layer 210 to determine the presence of a touch or touch coordinates, to provide a touch sensing function. Here, the touch sensor layer 210 may also be referred to as a touch unit or touch sensing unit.

For example, the touch sensing circuit may include a touch driving circuit 220 configured to drive and sense the touch sensor formed in the touch sensor layer 210 to generate and output touch sensing data, and a touch controller 230 configured to determine the presence of a touch or touch coordinates using the touch sensing data provided from the touch driving circuit 220.

The touch sensor layer 210 is a layer in which the touch sensor is formed, and the touch sensor may be composed of a plurality of touch electrodes.

For example, the touch sensor layer 210 may be disposed outside the display panel 110 and may be configured as a separate touch panel from the display panel 110. In this case, the touch panel and the display panel 110 may be separately manufactured or may be combined during an assembly process.

As another example, the touch sensor layer 210 may be embedded in the display panel 110. When the touch sensor layer 210 is included inside the display panel 110, the touch sensor layer 210 may be formed on the substrate 111, together with signal lines and electrodes related to display driving, during the manufacturing process of the display panel 110. For example, the touch sensor layer 210 may be disposed on the encapsulation layer 200. For convenience of description, an example where the touch sensor layer 210 is embedded in the display panel 110 is described below.

When the touch sensor layer 210 is embedded in the display panel 110, the display panel 110 may further include, in addition to the plurality of touch electrodes corresponding to the touch sensors, a plurality of touch pads TP to which the touch driving circuit 220 is electrically connected, and a plurality of touch routing lines TL electrically connecting the plurality of touch electrodes and the plurality of touch pads TP. Here, the plurality of touch routing lines TL may also be referred to as a plurality of touch lines. Further, the plurality of touch routing lines TL may correspond to a plurality of touch channels.

The touch driving circuit 220 may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between two adjacent touch electrodes. According to the mutual-capacitance sensing scheme, the plurality of touch electrodes are divided into driving touch electrodes and sensing touch electrodes. The touch driving circuit may drive the driving touch electrodes and sense the sensing touch electrodes. Touch routing lines connected to the driving touch electrodes may be referred to as driving touch routing lines, and touch routing lines connected to the sensing touch electrodes may be referred to as sensing touch routing lines.

The touch driving circuit 220 and the touch controller 230 may be implemented as separate devices or as a single device. The touch driving circuit 220 and the data driving circuit 120 may be implemented as separate devices or as a single device.

The touch display device 100 may further include a power supply circuit for supplying various types of power to the display driver integrated circuit and/or the touch sensing circuit. The power supply circuit may supply various voltages and power voltages related to display driving to the display driving circuit or display panel 110.

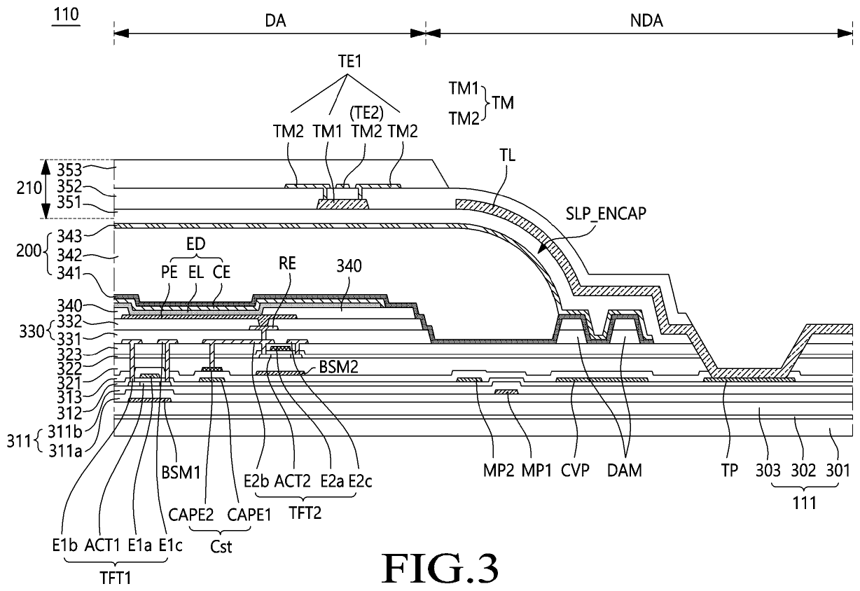

FIG. 3 is a cross-sectional view of a display panel 110 according to embodiments of the disclosure.

Referring to FIG. 3, the display panel 110 according to embodiments of the disclosure may include a substrate 111, a transistor unit, a light emitting element unit, and an encapsulation unit, but embodiments of the disclosure are not limited thereto.

The substrate 111 may be a single layer or multiple layers. When the substrate 111 includes multiple layers, the substrate 111 may include a first substrate 301, an intermediate substrate layer 302, and a second substrate 303. The intermediate substrate layer 302 may be positioned between the first substrate 301 and the second substrate 303. For example, each of the first substrate 301 and the second substrate 303 may be a polyimide (PI) layer, but embodiments of the disclosure are not limited thereto. The intermediate substrate layer 302 may be an inorganic insulation layer, but embodiments of the disclosure are not limited thereto. When an electric charge is charged to the first substrate PI1 which is a polyimide layer, the intermediate substrate layer 302 may prevent the electric charge from affecting transistors disposed on the second substrate 303 through the second substrate 303 which is a polyimide layer.

Further, the intermediate substrate layer 302 may prevent a moisture component from penetrating upward through the first substrate 301. For example, the intermediate substrate layer 302 may be formed of a single layer of silicon nitride (SiNₓ) or silicon oxide (SiOₓ) or multiple layers thereof, or may be formed of a double layer of silicon dioxide (SiO₂) and silicon nitride (SiNₓ), but is not limited thereto.

The transistor unit may include an insulation layer 311, 312, 313, 321, 322, and 323 on the substrate 111, thin film transistors TFT1 and TFT2, a storage capacitor Cst, and various electrodes or signal lines.

The thin film transistors TFT1 and TFT2 included in the transistor unit may include a first thin film transistor TFT1 and a second thin film transistor TFT2.

The first thin film transistor TFT1 may include a first active layer ACT1, a first electrode E1a, a second electrode E1b, and a third electrode E1c.

The first electrode E1a may be a gate electrode, the second electrode E1b may be a source electrode or a drain electrode, and the third electrode E1c may be a drain electrode or a source electrode. Hereinafter, for convenience of description, the first electrode E1a is referred to as a first gate electrode E1a, the second electrode E1b is referred to as a first source electrode E1b, and the third electrode E1c is referred to as a first drain electrode E1c, but embodiments of the disclosure are not limited thereto. However, embodiments of the disclosure are not limited thereto.

The first active layer ACT1 may include a first semiconductor material. For example, the first semiconductor material may include an oxide semiconductor, amorphous silicon, polysilicon, or low temperature polysilicon (LTPS), but embodiments of the disclosure are not limited thereto. The first thin film transistor TFT1 may be implemented as a p-channel transistor or an n-channel thin film transistor, but embodiments of the disclosure are not limited thereto.

The second thin film transistor TFT2 may include a second active layer ACT2, a fourth electrode E2a, a fifth electrode E2b, and a sixth electrode E2c.

The fourth electrode E2a may be a gate electrode, the fifth electrode E2b may be a source electrode or a drain electrode, and the sixth electrode E2c may be a drain electrode or a source electrode. Hereinafter, for convenience of description, the fourth electrode E2a is referred to as a second gate electrode E2a, the fifth electrode E2b is referred to as a second source electrode E2b, and the sixth electrode E2c is referred to as a second drain electrode E2c. However, embodiments of the disclosure are not limited thereto.

The second active layer ACT2 may include a second semiconductor material. For example, the second semiconductor material may include an oxide semiconductor, amorphous silicon, polysilicon, or low temperature polysilicon (LTPS), but embodiments of the disclosure are not limited thereto. The second thin film transistor TFT2 may be implemented as a p-channel transistor or an n-channel thin film transistor, but embodiments of the disclosure are not limited thereto.

The type of the semiconductor material of each of the first active layer ACT1 of the first thin film transistor TFT1 and the second active layer ACT2 of the second thin film transistor TFT2 may be as follows.

For example, the first active layer ACT1 of the first thin film transistor TFT1 and the second active layer ACT2 of the second thin film transistor TFT2 may include an oxide semiconductor material. As another example, the first active layer ACT1 of the first thin film transistor TFT1 and the second active layer ACT2 of the second thin film transistor TFT2 may include a low-temperature polysilicon semiconductor material. As another example, the first active layer ACT1 of the first thin film transistor TFT1 may include a low-temperature polysilicon semiconductor material, and the second active layer ACT2 of the second thin film transistor TFT2 may include an oxide semiconductor material. As another example, the first active layer ACT1 of the first thin film transistor TFT1 may include an oxide semiconductor material, and the second active layer ACT2 of the second thin film transistor TFT2 may include a low-temperature polysilicon semiconductor material.

The purposes of the transistors in the display area DA may be as follows.

For example, all of the transistors in each subpixel SP may be implemented as first thin film transistors TFT1. As another example, all of the transistors in each subpixel SP may be implemented as second thin film transistors TFT2. As another example, some of all of the transistors in each subpixel SP may be implemented as first thin film transistors TFT1, and the others of the transistors may be implemented as second thin film transistors TFT2. In other words, each subpixel SP may include at least one first thin film transistor TFT1 and at least one second thin film transistor TFT2.

When some of all of the transistors in each subpixel SP are implemented as first thin film transistors TFT1 and the others are implemented as second thin film transistors TFT2, the following examples may be possible.

For example, in each subpixel SP, the driving transistor DT may be implemented as a first thin film transistor TFT1, and other transistors (e.g., the scan transistor ST, the emission control transistor, etc.) than the driving transistor DT may be implemented as second thin film transistors TFT2.

As another example, in each subpixel SP, the driving transistor DT may be implemented as a second thin film transistor TFT2, and other transistors (e.g., the scan transistor ST, the emission control transistor, etc.) than the driving transistor DT may be implemented as first thin film transistors TFT1.

In FIG. 3, the second thin film transistor TFT2 connected to the pixel electrode PE of the light emitting element ED may be a driving transistor DT or a transistor different from the driving transistor DT according to the configuration of the subpixel circuit SPC. For example, in FIG. 3, the second thin film transistor TFT2 connected to the pixel electrode PE of the light emitting element ED may be an emission control transistor connected between the driving transistor DT and the light emitting element ED.

The purposes of the transistors in the non-display area NDA may be as follows.

For example, the active layers of the transistors included in the gate-in-panel (GIP) type gate driving circuit 130 may be formed of an oxide semiconductor material. As another example, the active layers of the transistors included in the gate-in-panel (GIP) type gate driving circuit 130 may be formed of a low-temperature polysilicon semiconductor material. As another example, among the transistors included in the gate-in-panel (GIP) type gate driving circuit 130, some active layers may be formed of a low-temperature polysilicon semiconductor material, and other active layers may be formed of an oxide semiconductor material.

The second active layer ACT2 of the second thin film transistor TFT2 may be positioned higher from the substrate 111 than the first active layer ACT1 of the first thin film transistor TFT1.

The first buffer layer 311 may be disposed under the first active layer ACT1 of the first thin film transistor TFT1, and a second buffer layer 321 may be disposed under the second active layer ACT2 of the second thin film transistor TFT2. For example, the first active layer ACT1 of the first thin film transistor TFT1 may be positioned on the first buffer layer 311, and the second active layer ACT2 of the second thin film transistor TFT2 may be positioned on the second buffer layer 321. The second buffer layer 321 may be positioned higher than the first buffer layer 311.

The storage capacitor Cst may be disposed in various metal layers in the display panel 110. For example, the storage capacitor Cst may include a first capacitor electrode CAPE1 and a second capacitor CAPE2.

The light emitting element portion may include a plurality of light emitting elements ED disposed on the second planarization layer 332. Each of the light emitting elements ED may include a pixel electrode PE, an intermediate layer EL, and a common electrode CE.

The encapsulation unit may include an encapsulation layer 200 on the plurality of light emitting elements ED. The encapsulation layer 200 may be a single layer or multiple layers, but embodiments of the disclosure are not limited thereto.

Hereinafter, a structure or a vertical structure of the display panel 110 according to embodiments of the disclosure is described in more detail with reference to FIG. 3.

Referring to FIG. 3, the first buffer layer 311 may be disposed on the substrate 111. The first buffer layer 311 may be a single layer or multiple layers, but embodiments of the disclosure are not limited thereto. When the first buffer layer 311 includes multiple layers, the first buffer layer 311 may include a lower buffer layer 311a and an upper buffer layer 311b.

The first active layer ACT1 of the first thin film transistor TFT1 may be disposed on the first buffer layer 311. The first active layer ACT1 may include a channel area in which a channel is formed, a source connection area on one side of the channel area, and a drain connection area on the other side of the channel area.

The first gate insulation layer 312 may be disposed on the first active layer ACT1 of the first thin film transistor TFT1. The first gate electrode E1a of the first thin film transistor TFT1 may be disposed on the first gate insulation layer 312. The first inter-layer insulation layer 313 may be disposed on the first gate electrode E1a of the first thin film transistor TFT1. Here, the metal layer where the first gate electrode E1a of the first thin film transistor TFT1 is disposed may be referred to as a gate metal layer.

The second buffer layer 321 may be disposed on the first inter-layer insulation layer 313.

The second active layer ACT2 of the second thin film transistor TFT2 may be disposed on the second buffer layer 321. The second active layer ACT2 may include a channel area in which a channel is formed, a source connection area on one side of the channel area, and a drain connection area on the other side of the channel area.

The second gate insulation layer 322 may be disposed on the second active layer ACT2 of the second thin film transistor TFT2. The second gate electrode E2a of the second thin film transistor TFT2 may be disposed. The second inter-layer insulation layer 323 may be disposed on the second gate electrode E2a of the second thin film transistor TFT2. Here, the second gate electrode E2a of the second thin film transistor TFT2 may be referred to as a second gate metal layer.

The first source electrode E1b and the first drain electrode E1c of the first thin film transistor TFT1, and the second source electrode E2b and the second drain electrode E2c of the second thin film transistor TFT2 may be disposed on the second interlayer insulation layer 323.

The first source electrode E1b and the first drain electrode E1c of the first thin film transistor TFT1 may be connected to the source connection area and the drain connection area, respectively, of the first active layer ACT1 through holes of the second inter-layer insulation layer 323, the second gate insulation layer 322, the second buffer layer 321, the first inter-layer insulation layer 313, and the first gate insulation layer 312.

The second source electrode E2b and the second drain electrode E2c of the second thin film transistor TFT2 may be connected to the source connection area and the drain connection area, respectively, of the second active layer ACT2 through the holes of the second inter-layer insulation layer 323 and the second gate insulation layer 322.

The first source electrode E1b and the first drain electrode E1c of the first thin film transistor TFT1, and the second source electrode E2b and the second drain electrode E2c of the second thin film transistor TFT2 may include a first source-drain metal and may be disposed in the first source-drain metal layer.

Referring to FIG. 3, e.g., the storage capacitor Cst may be formed by a first capacitor electrode CAPE1 and a second capacitor electrode CAPE2. In some cases, the storage capacitor Cst may be formed by three or more capacitor electrodes, or may have a form in which two or more capacitors are connected in parallel.

Each of the first capacitor electrode CAPE1 and the second capacitor electrode CAPE2 may be disposed on various metal layers disposed in the display panel 110.

For example, the first capacitor electrode CAPE1 may include the same first gate metal as the first gate electrode E1a of the first thin film transistor TFT1 on the first gate insulation layer 312 and may be disposed in the first gate metal layer, but embodiments of the disclosure are not limited thereto. For example, the second capacitor electrode CAPE2 may be disposed on the first inter-layer insulation layer 313.

The second source electrode E2b of the second thin film transistor TFT2 may be electrically connected to the second capacitor electrode CAPE2 through holes of the second inter-layer insulation layer 323, the second gate insulation layer 322, and the second buffer layer 321.

For example, when the subpixel SP is configured as shown in FIG. 2, the first thin film transistor TFT1 may be the scanning transistor ST of FIG. 2, and the second thin film transistor TFT2 may be the driving transistor DT of FIG. 2.

The transistor unit may further include at least one additional metal pattern MP1 and MP2. For example, the first pattern MP1 may be disposed between the lower buffer layer 311a and the upper buffer layer 311b included in the first buffer layer 311, but embodiments of the disclosure are not limited thereto. The second pattern MP2 may include the same first gate metal as the first gate electrode E1a of the first thin film transistor TFT1, and may be disposed in the first gate metal layer, but embodiments of the disclosure are not limited thereto.

Each of the first pattern MP1 and the second pattern MP2 may be disposed in the display area DA or the non-display area NDA.

Referring to FIG. 3, the transistor unit may further include a first shield pattern BSM1 disposed on the substrate 111. The first shield pattern BSM1 may overlap the first active layer ACT1 of the first thin film transistor TFT1. The first shield pattern BSM1 may be disposed under the first active layer ACT1 of the first thin film transistor TFT1. For example, the first shield pattern BSM1 may be disposed between the substrate 111 and the first buffer layer 311, or may be disposed between the lower buffer layer 311a and the upper buffer layer 311b.

The transistor unit may further include a second shield pattern BSM2 disposed on the substrate 111. The second shield pattern BSM2 may overlap the second active layer ACT2 of the second thin film transistor TFT2. The second shield pattern BSM2 may be disposed under the second active layer ACT2 of the second thin film transistor TFT2. For example, the second shield pattern BSM2 may be disposed in a metal layer between the first insulation layer 313 and the second buffer layer 321. The second shield pattern BSM2 may be disposed in the same metal layer as the second capacitor CAPE2, but embodiments of the disclosure are not limited thereto. As another example, the second shield pattern BSM2 may be disposed in the same first gate metal layer as the first gate electrode E1a of the first thin film transistor TFT1.

Referring to FIG. 3, the transistor unit may further include a common driving signal layer CV P to which a common driving signal is applied. The common driving signal layer CVP may be disposed in the display area DA or the non-display area NDA.

For example, the common driving signal applied to a common driving signal layer CVP may also be referred to as a power signal and may include at least one of a driving voltage VDD and a base voltage VSS. The driving voltage VDD may be referred to as a high-potential driving voltage (a high-potential power supply voltage or a high-potential voltage), and the base voltage VSS may be referred to as a low-potential driving voltage (a low-potential power supply voltage or a low-potential voltage).

The first planarization layer 331 and the second planarization layer 332 may be disposed on the first thin film transistor TFT1 and the second thin film transistor TFT2, and may be disposed under the light emitting element ED. The first planarization layer 331 and the second planarization layer 332 may be organic insulation layers including an organic insulating material.

For example, the first planarization layer 331 and the second planarization layer 332 may be formed as one layer. As another example, three or more layers including, e.g., a third planarization layer in addition to the first planarization layer 331 and the second planarization layer 332 may be disposed. Embodiments of the disclosure are not limited thereto.

Referring to FIG. 3, the first planarization layer 331 may be disposed on the first source electrode E1b and the first drain electrode E1c of the first thin film transistor TFT1, and the second source electrode E2b and the second drain electrode E2c of the second thin film transistor TFT2. For example, the first planarization layer 331 may be disposed on the first thin film transistor TFT1 and the second thin film transistor TFT2. For example, the first planarization layer 331 may be disposed while covering both the first thin film transistor TFT1 and the second thin film transistor TFT2.

Referring to FIG. 3, a connection electrode RE may be disposed on the first planarization layer 331. The connection electrode RE may electrically connect the second source electrode E2b of the second thin film transistor TFT2 and the pixel electrode PE.

The connection electrode RE may be electrically connected to the second source electrode E2b of the second thin film transistor TFT2 through the hole of the first planarization layer 331. The second source electrode E2b of the second thin film transistor TFT2 may be electrically connected to the second capacitor electrode CAPE2 of the storage capacitor Cst.

The connection electrode RE may be disposed in the second source-drain metal layer on the first planarization layer 331 and may include a second source-drain metal.

The second planarization layer 332 may be disposed on the connection electrode RE.

Referring to FIG. 3, the light emitting element unit may be disposed on the second planarization layer 332. The light emitting element ED may be formed on the second planarization layer 332. The light emitting element ED may include a pixel electrode PE, an intermediate layer EL, and a common electrode CE. The emission area of the light emitting element ED may be formed in an area in which the pixel electrode PE, the intermediate layer EL, and the common electrode CE overlap and contact each other.

The pixel electrode PE may be disposed on the second planarization layer 332. The pixel electrode PE may be electrically connected to the connection electrode RE through the hole of the second planarization layer 332.

A bank 340 may be disposed on the pixel electrode PE. The opening of the bank 340 may expose a portion of the pixel electrode PE to form the emission area. The opening of the bank 340 may overlap a portion of the pixel electrode PE.

For example, the bank 340 may be formed of a material including a black pigment, or an organic material such as a benzocyclobutene resin, a polyimide resin, an acrylic resin, or a photosensitive polymer, but embodiments of the disclosure are not limited thereto. When the bank 340 is formed of a material including a black pigment, a black dye, or the like, it may be a black bank. When the bank 340 is formed of a material including a black pigment or a black dye, light from the outside may be blocked or light reflected from the outside may be blocked, and thus the luminance of the touch display device 100 may be further enhanced.

The intermediate layer EL of the light emitting element ED may be disposed on a portion of the pixel electrode PE and the bank 340. The common electrode CE may be disposed on the intermediate layer EL.

Referring to FIG. 3, the encapsulation unit may be disposed on the light emitting element unit and may be positioned on the common electrode CE. The encapsulation unit may include the encapsulation layer 200 formed on the common electrode CE.

The encapsulation layer 200 may prevent moisture or oxygen from penetrating into the light emitting element ED. For example, the encapsulation layer 200 may prevent moisture or oxygen from penetrating into the organic material included in the intermediate layer EL of the light emitting element ED. The encapsulation layer 200 may be formed of a single layer or multiple layers, but embodiments of the disclosure are not limited thereto.

For example, the encapsulation layer 200 may include a first encapsulation layer 341, a second encapsulation layer 342, and a third encapsulation layer 343, but embodiments of the disclosure are not limited thereto. For example, the first encapsulation layer 341 and the third encapsulation layer 343 may include an inorganic layer, and the second encapsulation layer 342 may include an organic layer, but embodiments of the disclosure are not limited thereto. For example, the second encapsulation layer 342 may also be referred to as a particle cover layer (PCL). The second encapsulation layer 342 may include, e.g., a silicon oxycarbide (SiOCz), an acrylic or epoxy resin.

The encapsulation unit may include an encapsulation layer 200 on the plurality of light emitting elements ED. The encapsulation layer 200 may be a single layer or multiple layers, but embodiments of the disclosure are not limited thereto. In addition to the encapsulation layer 200, the encapsulation unit may further include a dam structure DAM for preventing a material constituting the encapsulation layer 200 from overflowing. In particular, when the second encapsulation layer 342 included in the encapsulation layer 200 is an organic encapsulation layer formed of an organic material, the dam structure DAM may prevent the second encapsulation layer 342 including the organic material from overflowing.

The display panel 110 according to embodiments of the disclosure may include a touch sensor TM. In this case, the display panel 110 according to embodiments of the disclosure may include a touch sensor layer 210 disposed on the encapsulation layer 200 and having a touch sensor TM.

Referring to FIG. 3, the touch sensor layer 210 may include a plurality of touch electrodes TE corresponding to touch sensors TM, and may include at least one touch metal layer for forming the plurality of touch electrodes TE.

For example, the touch sensor layer 210 may include a first touch metal layer on which a plurality of first touch metals TM1 are disposed, and a second touch metal layer on which a plurality of second touch metals TM2 are disposed, to form the plurality of touch electrodes TE. In this case, the touch sensor layer 210 may further include a touch interlayer insulation layer 352 disposed between the first touch metal layer and the second touch metal layer.

For example, one of the first touch metal layer and the second touch metal layer may be a sensor metal layer and the other may be a bridge metal layer.

For example, the first touch metal layer may be a bridge metal layer, and the second touch metal layer may be a sensor metal layer. In this case, the plurality of second touch metals TM2 disposed in the second touch metal layer may be sensor metals forming touch sensors TM, and the plurality of first touch metals TM1 disposed in the first touch metal layer may be bridge metals electrically connecting the plurality of second touch metals TM2, which are sensor metals. For example, two or more second touch metals TM2 and at least one first touch metal TM1 may constitute one first touch electrode TE1. In this case, two or more second touch metals TE2 may be electrically connected by at least one first touch metal TM1.

As another example, the first touch metal layer may be a sensor metal layer, and the second touch metal layer may be a bridge metal layer. In this case, the plurality of first touch metals TM1 disposed in the first touch metal layer may be sensor metals forming touch sensors TM, and the plurality of second touch metals TM2 disposed in the second touch metal layer may be bridge metals electrically connecting the plurality of first touch metals TM1, which are sensor metals.

As another example, each of the first touch metal layer and the second touch metal layer may be a sensor metal layer and a bridge metal layer. For example, the first touch metal layer may be a sensor metal layer and a bridge metal layer, and the second touch metal layer may be a sensor metal layer and a bridge metal layer. In this case, the plurality of first touch metals TM1 disposed in the first touch metal layer may include sensor metals and bridge metals, and the plurality of second touch metals TM2 disposed in the second touch metal layer may include sensor metals and bridge metals.

Referring to FIG. 3, the touch sensor layer 210 may further include a touch buffer layer 351 disposed on the encapsulation layer 200. The touch buffer layer 351 may be disposed between the encapsulation layer 200 and the touch metal layer. For example, the first touch metal layer may be disposed on the touch buffer layer 351, and the touch interlayer insulation layer 352 may be disposed on the first touch metal layer.

Referring to FIG. 3, the touch sensor layer 210 may further include a touch protection layer 353 disposed to cover the touch metal layer. For example, the touch protection layer 353 may be disposed on the second touch metal layer.

For example, the touch buffer layer 351 may be an inorganic layer including an inorganic insulating material or an organic layer including an organic insulating material, the touch interlayer insulation layer 352 may be an inorganic layer including an inorganic insulating material or an organic layer including an organic insulating material, and the touch protection layer 353 may be an inorganic layer including an inorganic insulating material or an organic layer including an organic insulating material.

For example, at least one of the touch buffer layer 351 and the touch interlayer insulation layer 352 may extend from the display area DA to the non-display area NDA. The touch protection layer 353 may be disposed to extend from the display area DA to the non-display area NDA.

The touch routing line TL may electrically connect the touch electrode TE and the touch pad TP. The touch routing line TL may be formed of at least one of the first touch metal TM1 and the second touch metal TM2.

For example, the touch routing line TL may be formed of the first touch metal TM1, or the touch routing line TL may be formed of the second touch metal TM2, or the first touch metal TM1 and the second touch metal TM2. When one touch routing line TL is formed of the first touch metal TM1 and the second touch metal TM2, the first touch metal TM1 and the second touch metal TM2 constituting one touch routing line TL may be electrically connected through a hole in the insulation layer 352.

For example, one touch routing line TL may include a plurality of wiring sections, and each of the plurality of wiring sections may be a single wiring section or a double wiring section. Here, the single wiring section may be a wiring section having one signal path, and the double wiring section may be a wiring section where two signal paths are connected in parallel.

The touch routing line TL may be disposed along the inclined surface SLP_ENCAP of the encapsulation layer 200, and may extend to the touch pad TP through the upper portion of the dam DAM.

The touch buffer layer 351 may have an opening exposing at least a portion of the touch pad TP. The touch routing line TL may be electrically connected to the touch pad TP through the opening of the touch buffer layer 351. The touch interlayer insulation layer 352 may be disposed on the touch routing line TL, and may extend to an area where the touch pad TP is disposed. The touch protection layer 353 may be disposed only in the display area DA, or may extend to the non-display area NDA to be disposed on the touch routing line TL. In some cases, the touch protection layer 353 may further extend to the upper portion of the touch pad TP.

Each of the plurality of touch electrodes TE may be a mesh-type electrode having a plurality of openings. In this case, each of the plurality of touch electrodes TE may be formed of at least one second touch metal TM2. However, embodiments of the disclosure are not limited thereto.

For example, the plurality of touch electrodes TE may include a first touch electrode TE1 and a second touch electrode TE2. When the first touch metal layer is a bridge metal layer and the second touch metal layer is a sensor metal layer, two or more second touch metals TM2 forming the first touch electrode TE1 corresponding to the touch sensor TM may be electrically connected through at least one first touch metal TM1, which are bridge metals. For example, the two second touch metals TM2 spaced apart from each other may be electrically connected by the first touch metal TM1 to constitute one first touch electrode TE1.

Referring to FIG. 3, the plurality of first touch metals TM1 and the plurality of second touch metals TM2 may be disposed not to overlap the light emitting element ED. The plurality of first touch metals TM1 and the plurality of second touch metals TM2 may overlap the bank 340. Accordingly, the luminous efficiency of the light emitting element ED may increase.

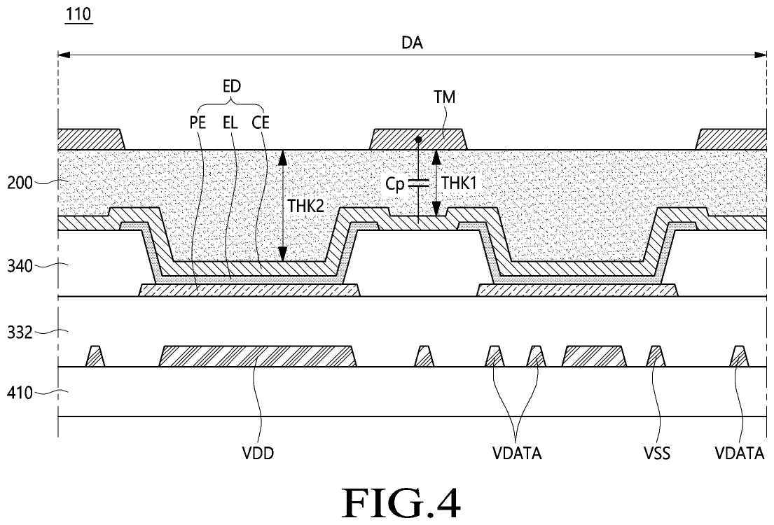

FIG. 4 is a cross-sectional view illustrating a portion of a display area DA in a display panel 110 according to embodiments of the disclosure.

Referring to FIG. 4, the display panel 110 according to embodiments of the disclosure may include a lower stack portion 410, a driving signal line, a second planarization layer 332, a light emitting element ED, a bank 340, an encapsulation layer 200, and a plurality of touch sensors TM, and a description overlapping the configuration of FIG. 3 may be omitted.

The lower stack portion 410 may include a substrate 111 including a display area DA and a non-display area surrounding the display area DA, a transistor unit disposed on the substrate 111, and a first planarization layer disposed on the transistor unit.

The driving signal line disposed on the first planarization layer may include lines for applying a data signal VDATA, a driving voltage VDD, a base voltage VSS, or the like, which are image signals, to subpixels. The data signal VDATA, driving voltage VDD, and base voltage VSS lines may include the same metal as the connection electrode connecting the pixel electrode PE of the light emitting element ED with the source electrode or the drain electrode of the transistor.

A second planarization layer 332 may be disposed on the driving signal line, the pixel electrode PE may be disposed on the second planarization layer 332, and a common electrode CE may be disposed on the pixel electrode PE.

Referring to FIG. 4, an encapsulation layer 200 may be disposed on the common electrode CE, and a plurality of touch sensors TM may be disposed on the encapsulation layer 200. Each of the plurality of touch sensors TM may overlap a portion of the bank 340.

The bank 340 may be disposed on the second planarization layer 332 while having a thickness larger than that of the light emitting element ED, and may be disposed between the pixel electrode PE and another pixel electrode PE adjacent to the pixel electrode PE.

Accordingly, a distance between the common electrode CE disposed on the bank 340 and the touch sensor TM may decrease. In other words, the thickness THK1 of the encapsulation layer 200 overlapping the plurality of touch sensors TM may be smaller than the thickness THK2 of the encapsulation layer 200 that does not overlap the plurality of touch sensors TM and does not overlap the bank 340.

All of the plurality of touch sensors TM and the common electrode CE are formed of a metal layer, and the distance between the plurality of touch sensors TM and the common electrode CE is decreased, thereby generating a parasitic capacitance Cp. In terms of touch sensing, the touch performance of the touch display device may be deteriorated due to the occurrence of the parasitic capacitance Cp that does not need to be formed

Capacitance may decrease as the dielectric constant of the dielectric decreases and the thickness of the dielectric increases. In the display panel 110 according to embodiments of the disclosure, the encapsulation layer 200 may be disposed between the common electrode CE and the plurality of touch sensors TM to function as a kind of dielectric. Therefore, the dielectric constant and thickness of the encapsulation layer 200 may be designed to reduce the parasitic capacitance Cp generated between the common electrode CE and the plurality of touch sensors TM.

For example, the parasitic capacitance Cp may decrease as the dielectric constant of the encapsulation layer 200 decreases or the thickness increases, but the disclosure is not limited thereto. Hereinafter, the encapsulation layer 200 capable of reducing the parasitic capacitance Cp is described in detail with reference to the drawings.

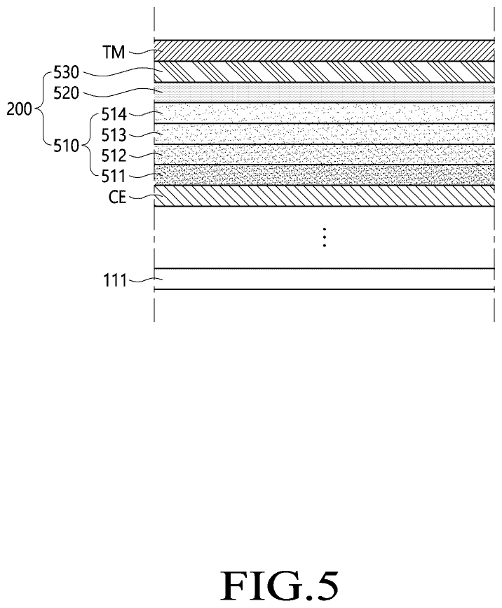

FIG. 5 is a cross-sectional view illustrating a detailed configuration of an encapsulation layer 200 in a display panel according to embodiments of the disclosure.

Referring to FIG. 5, the encapsulation layer 200 may include a first inorganic encapsulation layer 510 disposed on the common electrode CE, an organic encapsulation layer 520 disposed on the first inorganic encapsulation layer 510, and a second inorganic encapsulation layer 530 disposed on the organic encapsulation layer 520.

In the display panel according to embodiments of the disclosure, the dielectric constant of the first inorganic encapsulation layer 510 may be smaller than the dielectric constant of the second inorganic encapsulation layer 530, and the dielectric constant of the organic encapsulation layer 520 may be smaller than the dielectric constant of the first inorganic encapsulation layer 510.

By designing a magnitude relationship between the respective dielectric constants of the first inorganic encapsulation layer 510, the organic encapsulation layer 520, and the second inorganic encapsulation layer 530 as described above, the total dielectric constant of the encapsulation layer 200 may be decreased to reduce parasitic capacitance. The total dielectric constant of the encapsulation layer 200 may be calculated by dividing the total thickness of the encapsulation layer 200 by the sum of the values obtained by dividing the thickness of each of the first inorganic encapsulation layer 510, the organic encapsulation layer 520, and the second inorganic encapsulation layer 530 by the dielectric constant of each layer.

For example, each of the first inorganic encapsulation layer 510 and the second inorganic encapsulation layer 530 may include at least one of silicon nitride (SiNₓ), silicon oxide (SiOₓ), or silicon oxynitride (SiOₓN_{y}), but the disclosure is not limited thereto.

Among silicon nitride (SiNₓ), silicon oxide (SiOₓ), and silicon oxynitride (SiOₓN_{y}), silicon oxide (SiOₓ) may have the lowest dielectric constant. Therefore, at least one of the first inorganic encapsulation layer 510 and the second inorganic encapsulation layer 530 may be designed to include silicon oxide (SiOₓ), but the disclosure is not limited thereto.

However, silicon oxide (SiOₓ) has a lower effect of preventing moisture permeation than other inorganic materials such as silicon nitride (SiNₓ) and silicon oxide (SiOₓ), and thus it may be difficult to secure reliability of the display panel. Therefore, at least one of the first inorganic encapsulation layer 510 and the second inorganic encapsulation layer 530 is designed to form a multilayer film, thereby enhancing the moisture permeability resistance of the encapsulation layer 200.

Further, the first inorganic encapsulation layer 510 and the second inorganic encapsulation layer 530 may be formed as a multilayer film considering the optical characteristics of light emitted from the light emitting element. For example, by differently adjusting the refractive index or thickness of each multilayer film included in the first inorganic encapsulation layer 510 and the second inorganic encapsulation layer 530, the efficiency of light emitted from the light emitting element and passing through the encapsulation layer 200 may be increased.

Hereinafter, the encapsulation layer 200 having excellent moisture permeability resistance and reducing parasitic capacitance by including a plurality of inorganic layers is described in detail.

Referring to FIG. 5, in the display panel according to embodiments of the disclosure, the first inorganic encapsulation layer 510 may include a plurality of inorganic layers.

In the display panel according to embodiments of the disclosure, the first inorganic encapsulation layer 510 may include a plurality of inorganic layers having the same dielectric constant.

As the first inorganic encapsulation layer 510 includes a plurality of inorganic layers, the total thickness of the encapsulation layer 200 increases, so that parasitic capacitance may be decreased. Further, by disposing a plurality of inorganic layers, the moisture permeability resistance of the encapsulation layer 200 may be enhanced.

In the display panel according to embodiments of the disclosure, the first inorganic encapsulation layer 510 may include a plurality of inorganic layers having different dielectric constants.

In the display panel according to embodiments of the disclosure, among the plurality of inorganic layers having different dielectric constants, the inorganic layer closer to the substrate 111 may have a large dielectric constant. If the dielectric constant of the plurality of inorganic layers is described with respect to the touch sensor TM, among the plurality of inorganic layers, the inorganic layer closer to the touch sensor TM may have a smaller dielectric constant.

For example, the first inorganic encapsulation layer 510 may include a first inorganic layer 511 having a first dielectric constant, a second inorganic layer 512 having a second dielectric constant smaller than the first dielectric constant, a third inorganic layer 513 having a third dielectric constant smaller than the second dielectric constant, and a fourth inorganic layer 514 having a fourth dielectric constant smaller than the third dielectric constant.

In the display panel according to embodiments of the disclosure, the second inorganic encapsulation layer 530 may have the largest dielectric constant in the encapsulation layer 200.

In the display panel according to embodiments of the disclosure, the dielectric constant of the inorganic layer having the smallest separation distance from the substrate 111 among the plurality of inorganic layers may be smaller than or equal to the dielectric constant of the second inorganic encapsulation layer 530. In other words, the second inorganic encapsulation layer 530 may have a sixth dielectric constant equal to or larger than the first dielectric constant of the first inorganic layer 511.

In the display panel according to embodiments of the disclosure, the dielectric constant of the inorganic layer farthest from the substrate 111 among the plurality of inorganic layers may be larger than the dielectric constant of the organic encapsulation layer 520. In other words, the organic encapsulation layer 520 may have a fifth dielectric constant smaller than the fourth dielectric constant of the fourth inorganic layer 514.

Hereinafter, for convenience of description, the magnitude relationship between the first to sixth dielectric constants as described above may be described as a first condition.

In the display panel according to embodiments of the disclosure, the square root of a value obtained by multiplying the first dielectric constant and the third dielectric constant may be a second dielectric constant. In other words, the square of the second dielectric constant may be a value obtained by multiplying the first dielectric constant by the third dielectric constant. In other words, the second dielectric constant may be a geometric mean of the first dielectric constant and the third dielectric constant.

Hereinafter, for convenience of description, the relationship between the second dielectric constant and the first dielectric constant and the third dielectric constant as described above may be described as a second condition.

In the display panel according to embodiments of the disclosure, a difference between the fourth and fifth dielectric constants may be 1.0 or more.

Hereinafter, for convenience of description, the relationship between the fourth to fifth dielectric constants as described above may be described as a third condition.

By designing the first to sixth dielectric constants to meet the first to third conditions, the total dielectric constant of the encapsulation layer 200 is decreased, so that parasitic capacitance may be decreased.

Table 1 below illustrates the experimental results of four experiments (Experiments 1 to 4) identifying that the total dielectric constant of the encapsulation layer 200 decreases when the three conditions are met while changing the first to fourth dielectric constants of the first to fourth inorganic layers 511, 512, 513, and 514 included in the first inorganic encapsulation layer 510, the fifth dielectric constant of the organic encapsulation layer 520, and the sixth dielectric constant of the second inorganic encapsulation layer 530.

In Table 1, experimental results 1 are experimental results for the case where the first to sixth dielectric constants are set to meet all of the three conditions. Experimental results 2 are experimental results for the case where the first to sixth dielectric constants are set so that among the three conditions, the first and second conditions are met, but the third condition is not met. Experimental results 3 are experimental results for the case where the first to sixth dielectric constants are set so that among the three conditions, the second and third conditions are met but the first condition is not met. Experimental results 4 are experimental results for the case where the first to sixth dielectric constants are set so that among the three conditions, the second condition is met, but the first and third conditions are not met.

TABLE 1

| | Experimental | Experimental | Experimental | Experimental |
|---|---|---|---|---|
| | result 1 | result 2 | result 3 | result 4 |
| sixth dielectric constant | 5.8 | 5.8 | 5.8 | 5.8 |
| fifth dielectric constant | 2.6 | 3.2 | 3.2 | 3.2 |
| fourth dielectric constant | 3.9 | 3.9 | 5.8 | 3.9 |
| third dielectric constant | 4.5 | 4.5 | 5.8 | 4.5 |
| second dielectric constant | 5.1 | 5.1 | 5.8 | 5.4 |
| first dielectric constant | 5.8 | 5.8 | 5.8 | 6.5 |
| total dielectric constant | 2.9 | 3.5 | 3.6 | 3.6 |

As illustrated in Table 1, in the case of Experiment 1 meeting all of the three conditions, it may be identified that the total dielectric constant of the encapsulation layer 200 is the smallest as 2.9. Therefore, in Experiment 1, which meets all of the three conditions, it may be identified that the parasitic capacitance formed between the touch sensor TM and the common electrode CE is the smallest.

For touch sensing performance, the resistance-capacitance (RC) time constant of the touch sensor TM may be determined as the product of the resistance and capacitance of the touch sensor TM. Here, the RC time constant may also be referred to as a resistance-capacity (RC) delay.

As illustrated in Table 1, in the case of Experiment 1 meeting all of the three conditions, as the parasitic capacitance between the touch sensor TM and the common electrode CE is the smallest among the four experiments, the RC time constant may also have the smallest value. For the reason, when all of the three conditions are met, touch sensitivity may be significantly enhanced.

Further, as described above, according to the structure of the encapsulation layer 200 according to embodiments of the disclosure, noise components (e.g., DTX, DTN) that a common electrode (CE), a type of display driving electrode, affects the touch sensor TM may be decreased. For the reason, touch sensitivity may be further enhanced.

In the display panel according to embodiments of the disclosure, as the first inorganic encapsulation layer 510 includes the plurality of inorganic layers, the total thickness of the encapsulation layer 200 increases, so that parasitic capacitance may be decreased. Further, by disposing a plurality of inorganic layers, the moisture permeability resistance of the encapsulation layer 200 may be enhanced.

In the display panel according to embodiments of the disclosure, the second inorganic layer 512 and the third inorganic layer 513 may include the same inorganic material having different physical properties. For example, both the second inorganic layer 512 and the third inorganic layer 513 may include silicon oxynitride (SiOₓN_{y}), but the disclosure is not limited thereto.

In the case of the inorganic film included in the encapsulation layer 200, physical properties of the film may vary according to process parameters. For example, when the first to fourth inorganic layers 511, 512, 513, and 514 and the second inorganic encapsulation layer 530 included in the first inorganic encapsulation layer 510 are formed by a chemical vapor deposition (CVD) method, the physical properties of each layer may be varied by changing the flow rate of the input raw material gas, the power (W) used in the process, the pressure of the process chamber, and the process gap.

In other words, the second inorganic layer 512 and the third inorganic layer 513 included in the first inorganic encapsulation layer 510 may include silicon oxynitride (SiOₓN_{y}) having different dielectric constants, respectively.

In the display panel according to embodiments of the disclosure, the first inorganic layer 511 and the second inorganic encapsulation layer 530 may include the same inorganic materials having different physical properties. For example, the first inorganic layer 511 and the second inorganic encapsulation layer 530 may include silicon nitride (SiNₓ), but the disclosure is not limited thereto.

In other words, the first inorganic layer 511 and the second inorganic encapsulation layer 530, respectively, may include silicon nitride (SiNₓ) having different dielectric constants for the same reason as described above.

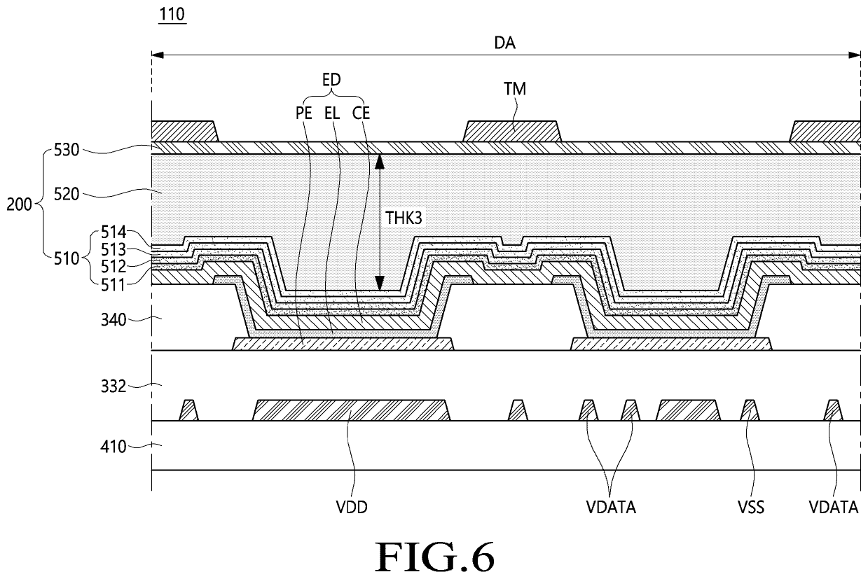

FIG. 6 is a cross-sectional view illustrating a portion of a display area DA in a display panel 110 according to embodiments of the disclosure.

Referring to FIG. 6, the display panel 110 according to embodiments of the disclosure may include a first inorganic encapsulation layer 510, an organic encapsulation layer 520, and a second inorganic encapsulation layer 530 disposed between the common electrode CE and the plurality of touch sensors TM. The first inorganic encapsulation layer 510 may include first to fourth inorganic layers 511, 512, 513, and 514.

As the first inorganic encapsulation layer 510 includes a plurality of inorganic layers, the total thickness of the encapsulation layer 200 increases, so that parasitic capacitance may be decreased. Further, by disposing the plurality of inorganic layers, the moisture permeability resistance of the encapsulation layer 200 may be enhanced.

The first to fourth inorganic layers 511, 512, 513, and 514, the organic encapsulation layer 520, and the second inorganic encapsulation layer 530 may have first to sixth dielectric constants, respectively. By defining the relationship between the first to sixth dielectric constants with the first to third conditions as described in FIG. 5, the total dielectric constant of the encapsulation layer 200 may be decreased, and the parasitic capacitance generated between the common electrode CE and the plurality of touch sensors TM may be decreased. As the parasitic capacitance is decreased, the touch sensitivity of the touch display device 100 according to embodiments of the disclosure may be enhanced.

Referring to FIG. 6, the display panel 110 according to embodiments of the disclosure may further include a light emitting unit EL disposed between the pixel electrode PE and the common electrode CE, and an area where the thickness THK3 of the organic encapsulation layer 520 is the thickest in the display area DA may overlap a portion of the light emitting unit EL.

By differently adjusting the refractive index and thickness of each of the first to fourth inorganic layers 511, 512, 513, and 514 and the second inorganic encapsulation layer 530, it is possible to increase the efficiency of light emitted from the light emitting unit EL and transmitted through the encapsulation layer 200.

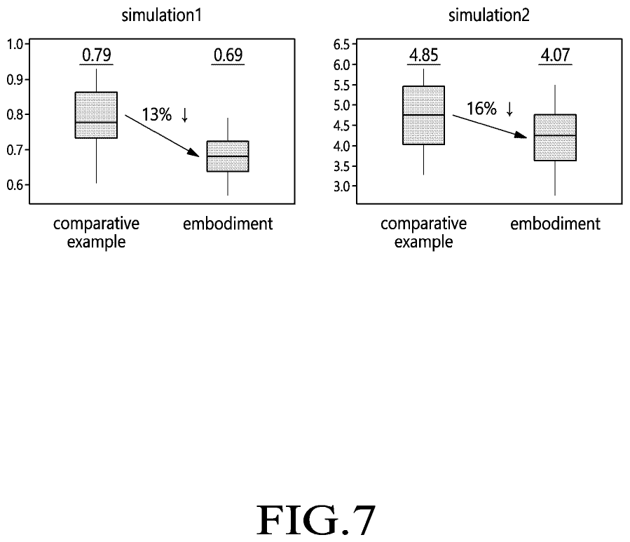

FIG. 7 illustrates display touch noise simulation results according to an embodiment of the disclosure and a comparative example.

In order to figure out the effects of the disclosure, as described above as an embodiment of the disclosure, a touch display device including first to fourth inorganic layers 511, 512, 513, and 514, an organic encapsulation layer 520, and a second inorganic encapsulation layer 530 meeting the first to third conditions was measured. As a comparative example of the disclosure, a touch display device including first to fourth inorganic layers 511, 512, 513, and 514, an organic encapsulation layer 520, and a second inorganic encapsulation layer 530 that do not meet the first to third conditions was measured as described above.

The graph of simulation 1 is the result of measuring display touch noise (DTN). DTN represents a standard deviation value of display noise generated between touch frames.

As illustrated in simulation 1, in the case of the touch display device according to the embodiment of the disclosure, it was identified that the DTN measurement value was decreased by about 13% compared to the touch display device of the comparative example.

The graph of simulation 2 is the result of measuring display touch crosstalk (DTX). DTX represents the amount of variation in the average display noise generated between touch frames relative to the black image.

As illustrated in simulation 2, in the case of the touch display device according to the embodiment of the disclosure, it was identified that the DTX measurement value was decreased by about 16% compared to the touch display device of the comparative example.

Through simulation 1 and simulation 2, it was identified that the touch display device including the first to fourth inorganic layers 511, 512, 513, and 514, the organic encapsulation layer 520, and the second inorganic encapsulation layer 530 meeting the first to third conditions may reduce noise generation during touch driving.

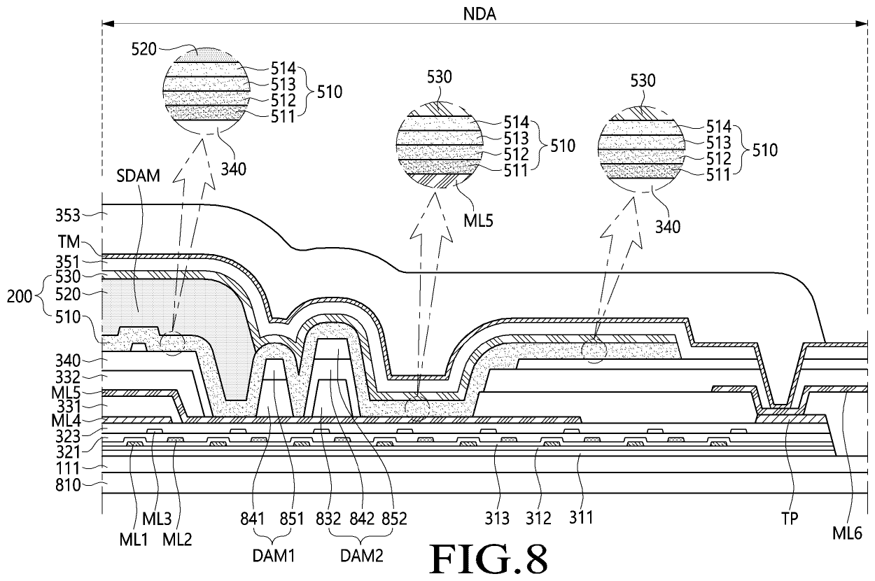

FIG. 8 is a cross-sectional view illustrating a portion of a non-display area NDA in a display panel 110 according to embodiments of the disclosure.

The display panel 110 according to embodiments of the disclosure may include a substrate 111, insulation layers 311, 312, 313, 321, and 323, a first planarization layer 331, a second planarization layer 332, a bank 340, or the like, and a description overlapping the configuration of FIG. 3 may be omitted.

Referring to FIG. 8, the display panel 110 according to embodiments of the disclosure may include a back plate 810 disposed under the substrate 111. The back plate 810 is a support member for maintaining the substrate 111 in a flat state. Since the substrate 111 may be formed of a material having flexibility, the back plate 810 may be used to maintain the shape of the touch display device, mechanical rigidity, or the like. The back plate 810 may be removed after the process of forming the display panel 110.

Referring to FIG. 8, the first inorganic encapsulation layer 510 may be disposed on the substrate 111, the organic encapsulation layer 520 may be disposed on the first inorganic encapsulation layer 510, and the second inorganic encapsulation layer 530 may be disposed on the organic encapsulation layer 520. Each of the first encapsulation layer 510, the organic encapsulation layer 520, and the second inorganic encapsulation layer 530 may be disposed in the display area and may extend to a partial area of the non-display area NDA. The first inorganic encapsulation layer 510 and the second inorganic encapsulation layer 530 may be disposed to extend further outward than the organic encapsulation layer 520.

Referring to FIG. 8, in the display panel 110 according to embodiments of the disclosure, the first inorganic encapsulation layer 510 may include first to fourth inorganic layers 511, 512, 513, and 514.

Referring to FIG. 8, an inner dam SDAM is positioned on the bank 340 to overlap the organic encapsulation layer 520, and the first to fourth inorganic layers 511, 512, 513, and 514 may extend from the display area to the outside of the inner dam SDAM along the upper portion of the inner dam SDAM. The first dam DAM1 is positioned near the edge of the organic encapsulation layer 520, and the first to fourth inorganic layers 511, 512, 513, and 514 and the second inorganic encapsulation layer 530 may extend from the display area to the outside of the first dam DAM1 along the upper portion of the first dam DAM1. The second dam DAM2 is positioned outside the first dam DAM1, and the first to fourth inorganic layers 511, 512, 513, and 514 and the second inorganic encapsulation layer 530 may extend from the display area to the outside of the second dam DAM2 along the upper portion of the second dam DAM2.

Therefore, referring to the enlarged view of the first inorganic encapsulation layer 510 near the inner dam SDAM, the first to fourth inorganic layers 511, 512, 513, and 514 extending to the outside of the inner dam SDAM along the upper portion of the inner dam SDAM may be disposed between the bank 340 and the organic encapsulation layer 520.

Referring to the enlarged view of the first inorganic encapsulation layer 510 near the second dam DAM2, the first to fourth inorganic layers 511, 512, 513, and 514 extending along the upper portions of the first dam DAM1 and the second dam DAM2 to the outside of the second dam DAM2 may be disposed between the fifth metal pattern ML5 and the second inorganic encapsulation layer 530.

Referring to the enlarged view of the first inorganic encapsulation layer 510 near the touch pad TP outside the second dam DAM2, the first to fourth inorganic layers 511, 512, 513, and 514 extending along the upper portion of the second dam DAM2 to the outside of the second dam DAM2 may be disposed between the bank 340 and the second inorganic encapsulation layer 530. In the case, the bank 340 is a kind of organic layer disposed in the non-display area NDA, and may include the same material as the bank disposed in the display area.

Referring to FIG. 8, a touch buffer layer 351 may be disposed on the second inorganic encapsulation layer 530, a touch sensor TM may be disposed on the touch buffer layer 351, and a touch protection layer 353 may be disposed on the touch sensor TM. In the non-display area NDA, the touch sensor may be formed of a single layer TM or a double layer including a first touch metal and a second touch metal, and the touch sensor TM may be a touch routing line electrically connected to the touch pad TP.

The first dam DAM1 may include a first lower dam 841 and a first spacer 851 contacting an upper portion of the first lower dam 841. The second dam DAM2 may include a second lower dam 832, a second intermediate dam 842, which is disposed to cover an upper portion of the second lower dam 832, and a second spacer 852 which contacts an upper portion of the second intermediate dam 842. The first and second spacers 851 and 852 may include the same material as the inner dam SDAM, but the disclosure is not limited thereto.

In the display panel 110 according to embodiments of the disclosure, the inner dam SDAM may assist the first dam and the second dams DAM1 and DA M 2 to prevent a flow of the organic material forming the organic encapsulation layer 520.

Referring to FIG. 8, the plurality of first to third metal patterns ML1, ML2, and ML3 may be disposed on the substrate 111 in the non-display area NDA. The first metal pattern ML1 and the second metal pattern ML2 may be signal lines or various electrodes. The first metal pattern ML1 may include the same metal as the first gate electrode E1a, and the second metal pattern ML2 may include the same metal as the second gate electrode E2a. The third metal pattern ML3 may be a layer that blocks the movement of electrons.

Referring to FIG. 8, a fourth metal pattern ML4 and a fifth metal pattern ML5 may be disposed on the substrate 111 in the non-display area NDA. The fourth metal pattern ML4 may be the first source electrode E1b or the first drain electrode E1c. Further, the fourth metal pattern ML4 may be the second source electrode E2b or the second drain electrode E2c. The fifth metal pattern ML5 may be a connection electrode RE electrically connecting the second source electrode E2b to the pixel electrode PE.

Referring to FIG. 8, a touch pad TP and a sixth metal pattern ML6 may be disposed on the substrate 111 in the non-display area NDA. The touch pad TP may include the same metal as the fourth metal pattern ML4, and the sixth metal pattern ML6 may include the same metal as the fifth metal pattern ML5. The sixth metal pattern ML6 may electrically connect the touch sensor TM and the touch pad TP.

Embodiments of the disclosure described above are briefly described below.

A touch display device according to embodiments of the disclosure may comprise a substrate including a display area and a non-display area surrounding the display area, a pixel electrode disposed on the substrate, a common electrode disposed on the pixel electrode, a first inorganic encapsulation layer disposed on the common electrode, an organic encapsulation layer disposed on the first inorganic encapsulation layer, a second inorganic encapsulation layer disposed on the organic encapsulation layer, and a touch sensor disposed on the second inorganic encapsulation layer. A dielectric constant of the first inorganic encapsulation layer may be smaller than a dielectric constant of the second inorganic encapsulation layer, and a dielectric constant of the organic encapsulation layer may be smaller than the dielectric constant of the first inorganic encapsulation layer.

The touch display device according to embodiments of the disclosure may further comprise a bank disposed between the pixel electrode and another pixel electrode adjacent to the pixel electrode. A thickness of the organic encapsulation layer overlapping the plurality of touch sensors may be smaller than a thickness of the organic encapsulation layer not overlapping the bank.

According to the touch display device according to embodiments of the disclosure, the first inorganic encapsulation layer may include a plurality of inorganic layers having different dielectric constants.

According to the touch display device according to embodiments of the disclosure, among the plurality of inorganic layers, an inorganic layer closer to the substrate may have a larger dielectric constant.

According to the touch display device according to embodiments of the disclosure, a dielectric constant of an inorganic layer closest to the substrate among the plurality of inorganic layers may be less than or equal to the dielectric constant of the second inorganic encapsulation layer, and a dielectric constant of an inorganic layer farthest from the substrate among the plurality of inorganic layers may be larger than the dielectric constant of the organic encapsulation layer.

According to the touch display device according to embodiments of the disclosure, the first inorganic encapsulation layer may include a first inorganic layer having a first dielectric constant, a second inorganic layer disposed on the first inorganic layer and having a second dielectric constant smaller than the first dielectric constant, a third inorganic layer disposed on the second inorganic layer and having a third dielectric constant smaller than the second dielectric constant, and a fourth inorganic layer disposed on the third inorganic layer and having a fourth dielectric constant smaller than the third dielectric constant.

According to the touch display device according to embodiments of the disclosure, the second dielectric constant may be a geometric mean of the first dielectric constant and the third dielectric constant.

According to the touch display device according to embodiments of the disclosure, the organic encapsulation layer may have a fifth dielectric constant smaller than the fourth dielectric constant, and a difference between the fourth dielectric constant and the fifth dielectric constant may be 1.0 or more.

According to the touch display device according to embodiments of the disclosure, the second inorganic encapsulation layer may have a sixth dielectric constant larger than or equal to the first dielectric constant.

According to the touch display device according to embodiments of the disclosure, the second inorganic layer and the third inorganic layer may include the same inorganic materials having different physical properties.

According to the touch display device according to embodiments of the disclosure, the first inorganic layer and the second inorganic encapsulation layer may include the same inorganic materials having different physical properties.

The touch display device according to embodiments of the disclosure may further comprise a first dam positioned adjacent to an edge of the second encapsulation layer. The first to fourth inorganic layers and the second inorganic encapsulation layer may extend from the display area to an outside of the first dam along an upper portion of the first dam.

The touch display device according to embodiments of the disclosure may further comprise an inner dam overlapping the second encapsulation layer. The first to fourth inorganic layers may extend from the display area to an outside of the inner dam along an upper portion of the inner dam.

The touch display device according to embodiments of the disclosure may further comprise a light emitting unit disposed between the pixel electrode and the common electrode. In the display area, an area in which the organic encapsulation layer may be thickest overlaps a portion of the light emitting unit.

A touch display device according to embodiments of the disclosure may comprise a substrate including a display area and a non-display area surrounding the display area, a pixel electrode disposed on the substrate, a common electrode disposed on the pixel electrode, an encapsulation layer disposed on the common electrode, and a plurality of touch sensors disposed on the encapsulation layer. The encapsulation layer may further include a first inorganic encapsulation layer including a plurality of inorganic layers, an organic encapsulation layer disposed on the first inorganic encapsulation layer, and a second inorganic encapsulation layer disposed on the organic encapsulation layer. Among the plurality of inorganic layers, an inorganic layer closer to the touch sensor may have a smaller dielectric constant.

According to the touch display device according to embodiments of the disclosure, the second inorganic encapsulation layer may have a largest dielectric constant in the encapsulation layer.

According to the touch display device according to embodiments of the disclosure, the first inorganic encapsulation layer may include a first inorganic layer having a smallest separation distance from the substrate among the plurality of inorganic layers. A dielectric constant of the first inorganic layer may be less than or equal to a dielectric constant of the second inorganic encapsulation layer.

According to the touch display device according to embodiments of the disclosure, the first inorganic encapsulation layer may include a first inorganic layer having a first dielectric constant, a second inorganic layer disposed on the first inorganic layer and having a second dielectric constant smaller than the first dielectric constant, a third inorganic layer disposed on the second inorganic layer and having a third dielectric constant smaller than the second dielectric constant, and a fourth inorganic layer disposed on the third inorganic layer and having a fourth dielectric constant smaller than the third dielectric constant.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A touch display device, comprising:
a substrate including a display area and a non-display area adjacent to the display area;
a pixel electrode on the substrate;
a common electrode on the pixel electrode;
a first inorganic encapsulation layer on the common electrode;
an organic encapsulation layer on the first inorganic encapsulation layer;
a second inorganic encapsulation layer on the organic encapsulation layer; and
a plurality of touch sensors on the second inorganic encapsulation layer,
wherein a dielectric constant of the first inorganic encapsulation layer is smaller than a dielectric constant of the second inorganic encapsulation layer, and
wherein a dielectric constant of the organic encapsulation layer is smaller than the dielectric constant of the first inorganic encapsulation layer.

2. The touch display device of claim 1, further comprising a bank between the pixel electrode and another pixel electrode adjacent to the pixel electrode,
wherein a thickness of the organic encapsulation layer overlapping the plurality of touch sensors is smaller than a thickness of the organic encapsulation layer not overlapping the bank.

3. The touch display device of claim 1, wherein the first inorganic encapsulation layer includes a plurality of inorganic layers having different dielectric constants.

4. The touch display device of claim 3, wherein among the plurality of inorganic layers, an inorganic layer closer to the substrate has a larger dielectric constant.

5. The touch display device of claim 3, wherein a dielectric constant of an inorganic layer closest to the substrate among the plurality of inorganic layers is less than or equal to the dielectric constant of the second inorganic encapsulation layer, and
wherein a dielectric constant of an inorganic layer farthest from the substrate among the plurality of inorganic layers is larger than the dielectric constant of the organic encapsulation layer.

6. The touch display device of claim 1, wherein the first inorganic encapsulation layer includes:
a first inorganic layer having a first dielectric constant;
a second inorganic layer on the first inorganic layer and having a second dielectric constant smaller than the first dielectric constant;
a third inorganic layer on the second inorganic layer and having a third dielectric constant smaller than the second dielectric constant; and
a fourth inorganic layer on the third inorganic layer and having a fourth dielectric constant smaller than the third dielectric constant.

7. The touch display device of claim 6, wherein the second dielectric constant is a geometric mean of the first dielectric constant and the third dielectric constant.

8. The touch display device of claim 6, wherein the organic encapsulation layer has a fifth dielectric constant smaller than the fourth dielectric constant, and
wherein a difference between the fourth dielectric constant and the fifth dielectric constant is 1.0 or more.

9. The touch display device of claim 6, wherein the second inorganic encapsulation layer has a sixth dielectric constant larger than or equal to the first dielectric constant.

10. The touch display device of claim 6, wherein the second inorganic layer and the third inorganic layer include the same inorganic materials having different physical properties.

11. The touch display device of claim 6, wherein the first inorganic layer and the second inorganic encapsulation layer include the same inorganic materials having different physical properties.

12. The touch display device of claim 6, further comprising a first dam positioned adjacent to an edge of the second encapsulation layer,
wherein the first to fourth inorganic layers and the second inorganic encapsulation layer extend from the display area to an outside of the first dam along an upper portion of the first dam.

13. The touch display device of claim 6, further comprising an inner dam overlapping the second encapsulation layer,
wherein the first to fourth inorganic layers extend from the display area to an outside of the inner dam along an upper portion of the inner dam.

14. The touch display device of claim 1, further comprising a light emitting unit between the pixel electrode and the common electrode,
wherein in the display area, an area in which the organic encapsulation layer is thickest overlaps a portion of the light emitting unit.

15. A touch display device, comprising:
a substrate including a display area and a non-display area adjacent to the display area;
a pixel electrode on the substrate;
a common electrode on the pixel electrode;
an encapsulation layer on the common electrode; and
a plurality of touch sensors on the encapsulation layer, wherein the encapsulation layer further includes:
a first inorganic encapsulation layer including a plurality of inorganic layers;
an organic encapsulation layer on the first inorganic encapsulation layer; and
a second inorganic encapsulation layer on the organic encapsulation layer, and
wherein among the plurality of inorganic layers, an inorganic layer closer to the touch sensor has a smaller dielectric constant.

16. The touch display device of claim 15, wherein the second inorganic encapsulation layer has the largest dielectric constant in the encapsulation layer.

17. The touch display device of claim 15, wherein the first inorganic encapsulation layer includes a first inorganic layer having a smallest separation distance from the substrate among the plurality of inorganic layers, and
wherein a dielectric constant of the first inorganic layer is less than or equal to a dielectric constant of the second inorganic encapsulation layer.

18. The touch display device of claim 15, wherein the first inorganic encapsulation layer includes:
a first inorganic layer having a first dielectric constant; and
a second inorganic layer on the first inorganic layer and having a second dielectric constant smaller than the first dielectric constant.

19. The touch display device of claim 18, wherein the first inorganic encapsulation layer includes:
a third inorganic layer on the second inorganic layer and having a third dielectric constant smaller than the second dielectric constant; and
a fourth inorganic layer on the third inorganic layer and having a fourth dielectric constant smaller than the third dielectric constant.
